(19) United States
(12) Patent Application Publication
(10) Pub. No.: US 2025/0336874 A1
(43) Pub. Date: Oct. 30, 2025

(54) SINTERING FOR SEMICONDUCTOR DEVICE ASSEMBLIES

(71) Applicant: SEMICONDUCTOR COMPONENTS INDUSTRIES, LLC, Scottsdale, AZ (US)

(72) Inventors: Hao YAN, Suzhou (CN); Kun FENG, Shanghai (CN); Yan YANG, Suzhou (CN); GuoQing YU, Suzhou (CN)

(73) Assignee: SEMICONDUCTOR COMPONENTS INDUSTRIES, LLC, Scottsdale, AZ (US)

(21) Appl. No.: 18/647,634

(22) Filed: Apr. 26, 2024

(51) Int. Cl. H01L 23/00

(52) U.S. Cl. CPC H01L 24/27; H01L 24/29; H01L 24/32; H01L 24/743; H01L 24/83; H01L 24/33; H01L 2224/27003; H01L 2224/2711; H01L 2224/27332; H01L 2224/277; H01L 2224/2781; H01L 2224/27848; H01L 2224/29139; H01L 2224/32225; H01L 2224/32245; H01L 2224/33181; H01L 2224/743; H01L 2224/83191; H01L 2224/83192; H01L 2224/8384; H01L 2924/10272; H01L 2924/10329; H01L 2924/1033

(57) ABSTRACT

In a general aspect, a method includes coupling a sintering film with a carrier tape cutting the sintering film into a plurality of sintering film portions, and removing a sintering film portion of the plurality of sintering film portions from the carrier tape. The method further includes disposing the sintering film portion on a surface of a semiconductor device assembly, and performing a thermal operation to couple the sintering film portion to the surface of the semiconductor device assembly.

### BACKGROUND

Sintering preform films (sintering preforms or preforms), such as silver-based (Ag-based) sintering preforms can be used for electrical and physical coupling of components in a semiconductor device package, such as for coupling a semiconductor die with a substrate or a die attach paddle, and/or coupling a signal lead or conductive clip with a substrate, die attach paddle or a semiconductor die. However, use of sintering preforms has a number of drawbacks. These drawbacks include yield loss due to damage and/or contamination, limitations on sintering preform size, and/or manufacturing efficiency impacts.

### SUMMARY

In a general aspect, a method includes coupling a sintering film with a carrier tape and cutting the sintering film into a plurality of sintering film portions. The method further includes removing a sintering film portion of the plurality of sintering film portions from the carrier tape and disposing the sintering film portion on a surface of a semiconductor device assembly. The method also includes performing a thermal operation to couple the sintering film portion to the surface of the semiconductor device assembly.

In another general aspect, a system for placement of sintering material in a semiconductor device assembly includes a pick and place apparatus, and a device assembly apparatus. The pick and place apparatus is configured to remove a portion of a sintering film from a carrier tape, and place the portion of the sintering film on a surface of the semiconductor device assembly, where the semiconductor device assembly is disposed on the device assembly apparatus, The device assembly apparatus is configured, after placement of the portion of the sintering film, to perform a thermal operation to couple the portion of the sintering film with the surface of the semiconductor device assembly.

In another general aspect, a method includes disposing an adhesive layer on a rigid polymer layer, and forming a sintering film on the adhesive layer by one of printing or jet spraying silver nanoparticles. The sintering film is a wafer-scale sintering film.

### BRIEF DESCRIPTION OF THE DRAWINGS

FIGS. 1A and 1B are diagrams illustrating an example wafer-scale sintering film that can be used for semiconductor device assembly manufacturing.

FIGS. 2A and 2B are diagrams illustrating example wafer-scale sintering films.

FIG. 3 is a diagram illustrating an example pick-and-place apparatus that can be used for handling sintering films during semiconductor device assembly manufacturing.

FIGS. 4A to 4F are diagrams illustrating an example sintering film pick-and-place and attachment process.

FIG. 5 is a flowchart illustrating an example method for placement and attachment of sintering films in a semiconductor device assembly.

FIG. 6 is a flowchart illustrating an example method for producing a wafer-scale sintering film, such as the sintering film of FIG. 1A.

FIG. 7 is a diagram illustrating an example semiconductor device assembly.

### DETAILED DESCRIPTION

At least one technical problem associated with the use of sintering preforms for forming electrical and physical interconnections in a semiconductor device assembly is damage to the sintering preforms during, at least, storage, shipping, and their handling in manufacturing. For instance, trays used for storage and shipping of sintering preforms have pockets (recesses, wells, etc.) that are specifically sized based on the dimensions of associated solder preforms. That is, the pockets of a given tray are sized based on the dimensions (e.g., length and width) of the sintering preforms they are used with. In such approaches, sintering preforms can be damaged during packing in, handling of, shipping of, and/or removal from trays in which they are stored, e.g., due to collision with walls of the pockets. This damage can result in yield loss (e.g., discarded sintering preforms), which can increase manufacturing costs, and/or can result in poor quality sintering connections, e.g., where a damaged sintering preform is used in a device assembly). Furthermore, the likelihood of such damage increases with sintering preform size. That is, larger sintering preforms are more susceptible to being damaged. Accordingly, in such prior approaches, sizes of such sintering preforms are limited in order to reduce the incidence of such damage.

Another technical problem with prior approaches is the use of different trays for differently sized sintering preforms (e.g., with appropriately sized pockets), which adds to the cost associated with packaging and shipping of sintering preforms of different sizes and, in turn, increases associated product manufacturing costs for semiconductor device assemblies in which differently sized preforms are used. This use of different trays, e.g., with respective pocket sizes for corresponding sintering preforms, can also reduce manufacturing efficiency. For instance, for a semiconductor device assembly that is produced using multiple sintering preforms of different sizes, associated trays holding the different sizes of preforms need to be changed during production of such device assemblies. The time needed for changing trays for different sintering preforms adversely impacts a number of assemblies that can be produced in a given period of time, e.g., units per hour (UPH).

Still another technical problem with prior approaches is peeling of sintering preforms after attachment in a semiconductor device assembly. Such peeling can occur as a result of contamination of a sintering preform. Such contamination can occur during packing of the sintering preforms in pockets of an associated tray, e.g. due to contaminants present in the pocket, or can occur during shipping and or subsequent handling of the sintering preforms and associated trays.

Yet another technical problem with prior approaches is difficult in removing (releasing) a protective (e.g., polymer layer) from a sintering preform after attachment of the preform to a surface of a component of a semiconductor device assembly, such as after performing a hot tack operation. A hot tack operation, as used herein, is a thermal process used to affix a sintering preform to an underlying structure, such as a substrate, die attach paddle, semiconductor die, etc., until a sintering operation (e.g., pressure sintering operation) is performed to form a sintered connection using the sintering film.

One technical solution to at least some of the aforementioned technical problems can be the use of wafer-scale sintering films during semiconductor device package manufacturing. Such wafer-scale sintering films can have dimensions similar to those of a semiconductor wafer. Such wafer-scale sintering films can be cut into individual sintering film portions of appropriate size(s). Those sintering film portions can be removed (picked) from a carrier tape, e.g., a low-tack polymer tape, such as a die transfer film. A picked sintering film portion can be transferred to, and placed in a semiconductor assembly, such as on a substrate, a die attach paddle, or a semiconductor die, equipment. That is, a sintering film wafer can be cut, e.g., by laser saw or other approach, to produce sintering films of a desired size or sizes, similar to singulating semiconductor die from a semiconductor wafer. After cutting, the individual (e.g., singulated) sintering films (sintering film chips) can then be picked and placed as part of a sintering process.

At least one technical effect of the foregoing technical solution is the elimination of the use of custom trays for packing and shipping of sintering preforms, and for use during manufacturing. At least one benefit of this technical solution is reduction and/or prevention of sintering film damage during packing and shipping in trays, and during removal from those trays during semiconductor device assembly manufacturing. At least another benefit of this technical solution is improved manufacturing efficiency, as swapping of trays for differently sized sintering preforms can be eliminated.

At least another technical effect of the foregoing technical solution is reduction and/or elimination of contamination to sintering films. At least one benefit of this technical solution is reduction or elimination of peeling of sintering films after attachment (e.g., hot tack) to surface of a component of a semiconductor assembly.

Another technical solution to at least some of the aforementioned technical problems is the use of an ultraviolet (UV) curable adhesive to couple a wafer-scale sintering film with a protective (e.g., rigid) polymer layer (film, tape, etc.). For example, at least one UV light source can be included in a semiconductor device assembly tool, such as an inspection tool (e.g., a part vision table including an inspection camera). In this example, the UV light source(s) can be used (e.g., before, during, and/or after) visual inspection of a sintering film portion, where the UV light cures the UV curable adhesive. One benefit of this technical solution is the reduction of a peeling force for removing the protective polymer layer from a respective sintering film portion after attachment (e.g., hot tack) to a component of a semiconductor device assembly, which can reduce and/or eliminate yield loss associated with unremoved protective films.

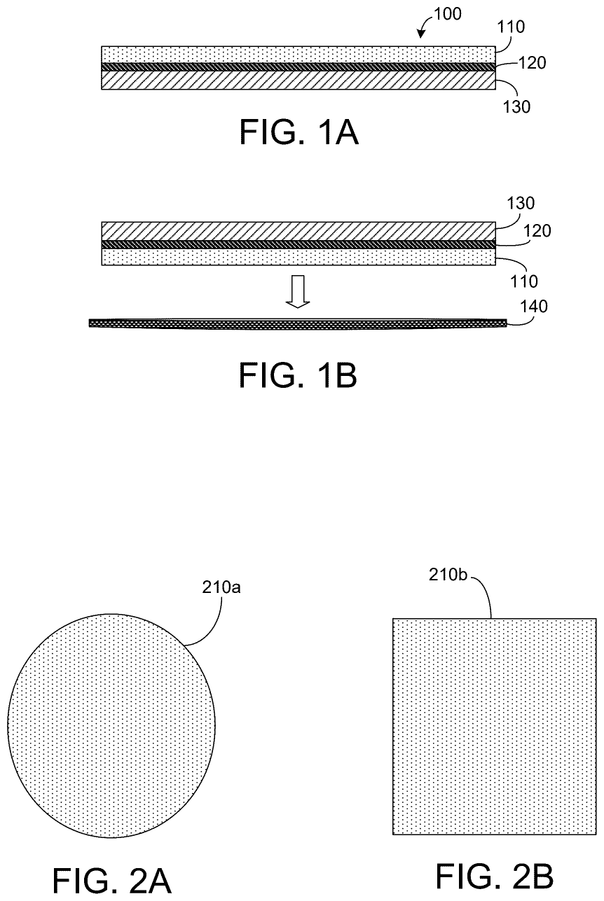

FIGS. 1A and 1B are diagrams illustrating an example sintering film stack 100 that can be used for semiconductor device assembly manufacturing. As used herein, a wafer-scale sintering film refers to a sintering film having similar dimensions as a standard semiconductor wafer. For instance, in some implementations, a wafer-scale sintering film can have a disc (circular) shape with a diameter of 6 inches (in), 8 in, 10 in, or 12 in. In some implementations, a wafer-scale sintering film can have other shapes, such as a square shape, an oval shape, an octagonal shape, etc. In some implementations, wafer handling equipment (e.g., with minor modifications) can be used during semiconductor device package manufacturing for transferring portions of the wafer-scale sintering film (e.g., formed by cutting the wafer-scale sintering film) from a carrier tape, such as a die transfer film, to components of a semiconductor device assembly (package), such as a substrate, a die attach paddle, or a semiconductor die. In some implementations, different size sintering films for a given semiconductor package can be cut from a single, wafer-scale sintering film, and those differently sized sintering films can be respectively placed on corresponding surfaces of components of the semiconductor package.

As shown in FIG. 1A, the sintering film stack 100 includes a wafer-scale sintering film 110. The wafer-scale sintering film 110 is disposed on an adhesive layer 120, which couples the wafer-scale sintering film 110 to a protective layer 130. In some implementations, such as examples described herein, the adhesive layer 120 can be curable using ultraviolet (UV) light, e.g., to reduce its adhesion strength. Such curing can facilitate ease of removal of respective portions of the protective layer 130 from corresponding portions of the wafer-scale sintering film 110, such as after performing a thermal operation (hot tack operation) to couple the sintering film portion to a component of a semiconductor device assembly.

For instance, the adhesive layer 120 can be a UV curable acrylate such as acrylic UV-curable polymer tape. In some implementations, use of a UV curable material for the adhesive layer 120 can, as compared to prior approaches, reduce a force used to remove a polymer tape from a corresponding sintering film portion by approximately seventy percent. In some implementations, UV curing of the sticker layer can be performed as part of visual inspection of the sintering film portion. For instance a visual inspection tool, e.g., a vision table, can be modified to include one or more UV lights to facilitate such curing. In example implementations, UV curing can be done before, during, and/or after visual inspection is performed.

In some implementations, the protective layer 130 can be a rigid, polymer layer, such as a rigid, polymer tape. In some implementations, the sintering film stack 100, along with other wafer-scale sintering film stacks, can be placed in an appropriately sized semiconductor wafer carrier box for handling and/or shipment, which can prevent damage to the wafer-scale sintering film 110 and/or contamination of the wafer-scale sintering film 110 associated with the use of custom trays for sintering preforms. The sintering film stack 100 can then be transported to a semiconductor device package manufacturing facility.

As shown in FIG. 1B, the sintering film stack 100 can, e.g., at a semiconductor package manufacturing facility, be coupled with a carrier tape 140, which can be a die transfer film that is appropriately sized based on dimensions of the sintering film stack 100 and/or the wafer-scale sintering film 110. The sintering film stack 100, as shown in FIG. 1B, is inverted from the view of the sintering film stack 100 in FIG. 1A.

FIGS. 2A and 2B are diagrams illustrating example wafer-scale sintering films. For instance, FIG. 2A illustrates a circular-shaped (disc) wafer-scale sintering film 210a, and FIG. 2B illustrates a square-shaped wafer-scale sintering film 210b. In the examples of FIGS. 2A and 2B, an adhesive layer (such as the adhesive layer 120) and a protective layer (such as the protective layer 130) can be disposed on a backside of the circular-shaped wafer-scale sintering film 210a and the square-shaped wafer-scale sintering film 210b. Accordingly, the adhesive layer and the protective layer are not visible in the views of FIGS. 2A and 2B. The circular-shaped wafer-scale sintering film 210a and the square-shaped wafer-scale sintering film 210b are given by way of example. In some implementations, a wafer-scale sintering film can have other shapes, such as octagon shapes, rectangle shapes, and so forth.

In some implementations, wafer-scale sintering films of a desired thickness (such as the wafer-scale sintering films 110, 210a and 210b) can be produced using additive printing, e.g., 3-dimensional printing, and/or jet spraying with a nano Ag-filler on a UV curable adhesive layer disposed on a protective layer, such as a rigid polymer tape. For instance, a jet-sprayed sintering film can have a thickness of 60 to 70 micrometers (μm) and a sintering film formed using additive printing can have a thickness of 95 to 105 μm, not including a thickness of corresponding protective and adhesive layers. As described herein, such wafer-scale sintering film wafers can be produced with standard semiconductor wafer sizing. After formation, sintering film wafers can then be placed in standard wafer boxes (as discussed above) and/or mounted in standard wafer rings, for transport, storage, and/or use in a sintering operation of a semiconductor device package assembly manufacturing process.

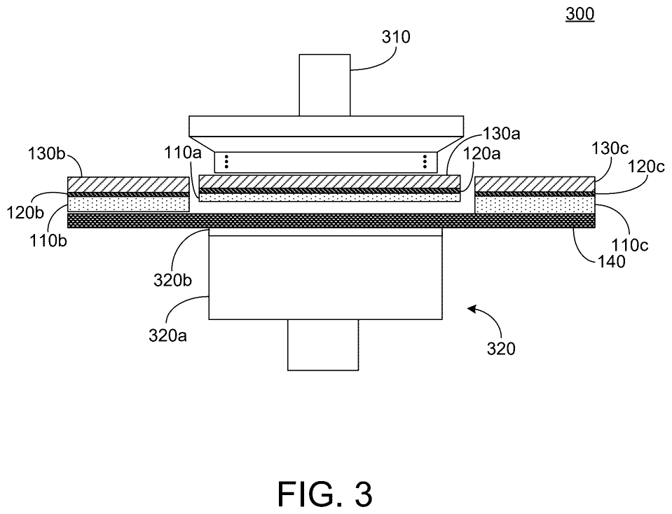

FIG. 3 is a diagram illustrating an example pick-and-place apparatus 300 that can be used for handling sintering films during semiconductor device assembly (package) manufacturing. By way of example, and for purposes of illustration, the pick-and-place apparatus 300 of FIG. 3 is shown in conjunction with the sintering film stack 100 of FIGS. 1A and 1B, e.g., after cutting the wafer-scale sintering film 110 into a plurality of sintering film portions, including sintering film portions 110a, 110b and 110c, with respective adhesive layer portions 120a, 120b and 120c, and respective protective layer portions 130a, 130b and 130c. In the view of FIG. 3, only a portion of the wafer-scale sintering film 110, e.g., three sintering film portions are shown for purposes of illustration. In example implementations, a wafer-scale sintering film can be cut into other numbers of sintering film portions of one or more sizes (width and length), such as hundreds or thousands of sintering film portions of one or more sizes.

As shown in FIG. 3, the pick-and-place apparatus 300 includes a vacuum head 310 and a pepper pot 320. The vacuum head 310 can be connected to vacuum supply line which can be used to selectively apply and remove vacuum pressure to the vacuum head 310 for picking (removing) sintering film portions of a wafer-scale sintering film from the carrier tape 140 and transferring them to corresponding surfaces of components of a semiconductor device package or assembly (such as a substrate, die attach paddle, or semiconductor die). In some implementations including a substrate, the substrate can be a direct-bonded-metal (DBM) substrate, such as a direct-bonded-copper (DBC) substrate. For instance, a DBM substrate can include an insulator layer (e.g., a ceramic layer), a first metal layer (e.g., a patterned metal layer including electrically conductive traces) disposed on a first side of the insulator layer, and a second metal layer (e.g., for attaching a heat sink) disposed on an opposite side of the insulator layer. In some implementations, such as DBC implementations, the first metal layer and the second metal layer are copper layers.

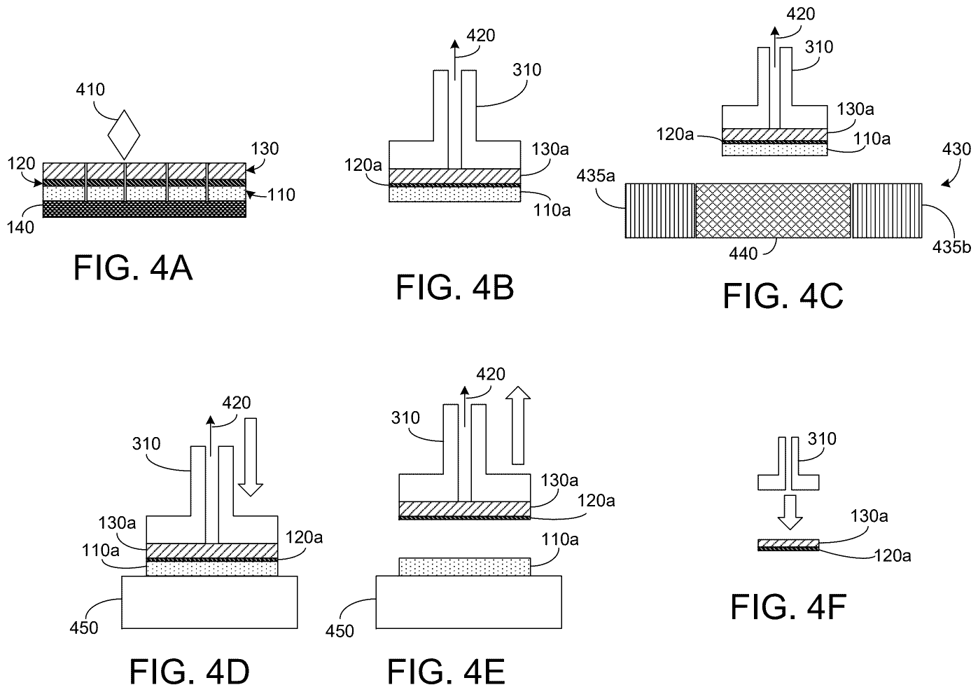

Once a sintering film portion (sintering film portion 110a) is placed and coupled to a corresponding surface in a semiconductor device assembly, e.g., via a hot tack operation, the corresponding protective layer portion (protective layer portion 130a) is removed from the sintering film portion by the vacuum head 310. After removing the protective layer portion, vacuum pressure to the vacuum head 310 can be removed (disabled) to release the protective layer portion, which can then be discarded. This process is shown in FIGS. 4A-4F and discussed further below.

As shown in FIG. 3, the pepper pot 320 includes a support 320a and a resilient surface 320b (e.g., a rubber sheet). In this example implementation, the pepper pot 320 provides support for sintering film portions, e.g., the sintering film portion 110a, when being picked (removed) from the carrier tape 140. That is, the support 320a and the resilient surface 320b provide support for the sintering film portions 110a when being removed from the carrier tape 140, with the resilient surface 320b preventing damage, such as cracking, of the sintering film portions when they are contacted by the vacuum head 310 and removed from the carrier tape 140. In some implementations, the pepper pot 320 can be included in a modified die bonder table, which can include a camera used for part vision during a semiconductor device package manufacturing process, as well as one or more UV light sources for curing respective adhesive layer portions, e.g., such as the adhesive layer portion 120a in this example.

FIGS. 4A to 4F are diagrams illustrating an example process for picking, placing, and attaching sintering film portions of a wafer-scale sintering film portions as part of a semiconductor device package or assembly manufacturing process. The process of FIGS. 4A to 4F is illustrated and described in conjunction with the example implementations of FIG. 1A, 1B and 3. As shown in FIG. 4A, the sintering film stack 100 of FIG. 1A has been coupled with the carrier tape 140, such as described with respect to FIG. 1B. The wafer-scale sintering film 110 of the sintering film stack 100 is then cut, e.g., using a laser cutter 410, into a plurality of sintering film portions, w110hich can be of a same size or different sizes, depending on the particular implementation.

As shown in FIG. 4B, after cutting the wafer-scale sintering film 110 into sintering film portions, the vacuum head 310 can be used to pick (remove) the sintering film portions, e.g., the sintering film portion 110a, from the carrier tape 140 using a vacuum pressure 420 that is applied to the vacuum head 310. As shown in FIG. 4B, the adhesive layer portions 120a and the protective layer portions 130a are also picked along with the sintering film portion 110a.

As schematically illustrated in FIG. 4C, the picked sintering film portion 110a, adhesive layer portion 120a, protective layer portion can be moved to an inspection apparatus 430, e.g., a modified die bonder vision table. The inspection apparatus 430 includes a camera 440 that is configured to visually inspect the sintering film portion 110a for any damage. The inspection apparatus 430 also includes UV light sources 435a and 435b. The UV light sources 435a and 435b, in this example, can provide UV light for curing the adhesive layer portion 120a, e.g., to facilitate ease of removal of the protective layer portion 130a from the sintering film portion 110a. Curing of the adhesive layer portion 120a by the UV light sources 435a and 435b can be performed before, during, and/or after visual inspection of the sintering film portion 110a, where such visual can be automated by the inspection apparatus 430.

After the inspection and curing operations of FIG. 4C, as shown in FIG. 4D, the sintering film portion 110a is then be placed on a desired surface of a component 450 of a semiconductor device package or assembly, such as a die attach paddle, a substrate, or a semiconductor die, and the sintering film portion 110a can then be hot tacked to the surface of the component 450. For instance, the vacuum head 310 can apply pressure to the sintering film portion 110a and the component 450 can be heated, e.g., to 150 degrees centigrade using a heat source included in the inspection apparatus 430 or a heat source included in a hot tack tool.

As shown in FIG. 4E, after the hot tack operation of FIG. 4D, the vacuum head 310 can be raised from the sintering film portion 110a to remove the protective layer portion 130a and a remaining portion of the adhesive layer portion 120a (now cured). In some implementations, some portion of the cured adhesive layer portion 120a may remain on the upper surface of the sintering film portion 110a, which can be removed by a clean operation, so as not to affect a subsequent sintering operation, e.g., a pressure sintering operation to couple another component of a semiconductor device assembly to the component 450. For instance, the adhesive layer portion 120a is removed from the surface of the component 450 in FIGS. 4D and 4E. In some implementations, some portion of the adhesive layer portion 120a (cured) may remain on the protective layer portion 130a.

As shown in FIG. 4F, after removing the protective layer portion 130a (and any corresponding portion of the cured adhesive layer portion 120a) from the sintering film portion 110a and performing a clean operation, the vacuum pressure 420 to the vacuum head 310 can be disabled to release the protective layer portion 130a, which can be discarded. The operations of FIGS. 4B to 4F can then be repeated for picking and placing additional sintering film portions. In some implementations, the operations illustrated in FIGS. 4C, 4D and 4E can be performed using a single tool or apparatus (e.g., a modified die bonder table including a heat source), or can be performed using separate apparatus (e.g., a modified die bonder table and a separate hot tack apparatus or tool).

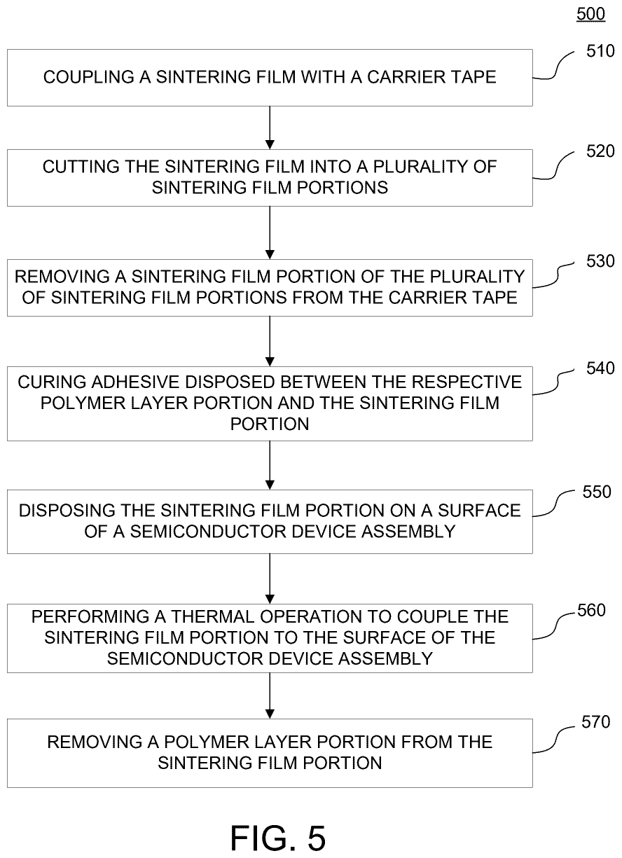

FIG. 5 is a flowchart illustrating an example method 500 for placement and attachment of sintering films in a semiconductor device assembly. In some implementations, the method 500 can be implemented using the example approaches, techniques and aspects described herein. Accordingly, for purposes of illustration, reference is made to elements of FIGS. 1A, 1B, 3 and 4A-4F in the discussion of the method 500.

At block 510, the method 500 includes coupling a sintering film with a carrier tape, such as coupling the wafer-scale sintering film 110 with the carrier tape 140. The sintering film can be a silver-based sintering film. Further, the sintering film can be coupled with a protective layer, e.g., the protective layer 130, via an adhesive layer, e.g., the adhesive layer 120, such as the sintering film stack 100. As described herein, the adhesive layer can be a UV curable acrylate, the protective layer can be a rigid, polymer layer or tape, and the carrier tape can be a resilient, low-tack polymer tape, such as a die transfer film.

At block 520, the method 500 includes cutting the sintering film into a plurality of sintering film portions, which can include cutting the protective layer into a plurality of respective protective layer portions and respective adhesive layer portions. The plurality of sintering film portions can be of a same size, or can be of different sizes. At block 530, the method 500 includes removing (picking) the sintering film portion from the carrier tape, e.g., with the vacuum head 310. Removing the sintering layer portion can also include removing a respective adhesive layer portion and a respective protective layer portion.

At block 540, the method 500 includes curing the adhesive layer portion with at least one UV light source, which can be performed using an optical inspection tool, such as the inspection apparatus 430. At block 550, the method 500 includes transferring and placing (disposing) the sintering film portion on a surface of a component of a semiconductor device package or assembly, such as a substrate (a direct-bonded metal substrate), a die attach paddle or a semiconductor die. At block 560, the method 500 includes performing a thermal operation, e.g., a hot tack operation, to couple the sintering film portion to the surface of the component of the semiconductor device assembly on which it was placed at block 540.

At block 570, after performing the thermal operation, the method 500 includes removing the respective protective layer portion (and cured adhesive layer) from the sintering film portion with the vacuum head. After block 570, the vacuum pressure can be removed from the vacuum head, which will release the protective layer portion (and cured adhesive layer portion), which can then be discarded.

In some implementations, after releasing the protective layer portion, the method 500 can be resumed at block 530 for picking and placing another sintering film portion, or additional components can be placed in a corresponding semiconductor device assembly, and then the method 500 can resume at block 530 to place one or more additional sintering film portions. For instance, as one example, the method 500 can be performed to place and hot tack a first sintering film portion on a substrate. A semiconductor die can then be placed on the first sintering film and a second sintering film portion can be placed and hot tacked on the semiconductor die. A contact surface of a signal lead or conductive clip can then be disposed on the second sintering film portion, and a pressure sintering operation can be performed to electrically and physically couple the semiconductor die with the substrate, and electrically and physically couple the signal lead (or conductive clip) with the semiconductor die. As described herein, the first sintering film portion and the second sintering film portion (as well as additional sintering film portions) can be the same size, or can be different sizes.

In some implementations, the method 500 can be implemented to place two or more sintering film portions (including one or more hot tack operations) and place respective semiconductor die on the two or more sintering film portions. For instance, a semiconductor device assembly produced using the method 500 can include a first semiconductor die including silicon carbide and a second semiconductor die including silicon. In some implementation, semiconductor die including other semiconductor materials can be included, such as gallium nitride, gallium arsenide, etc.

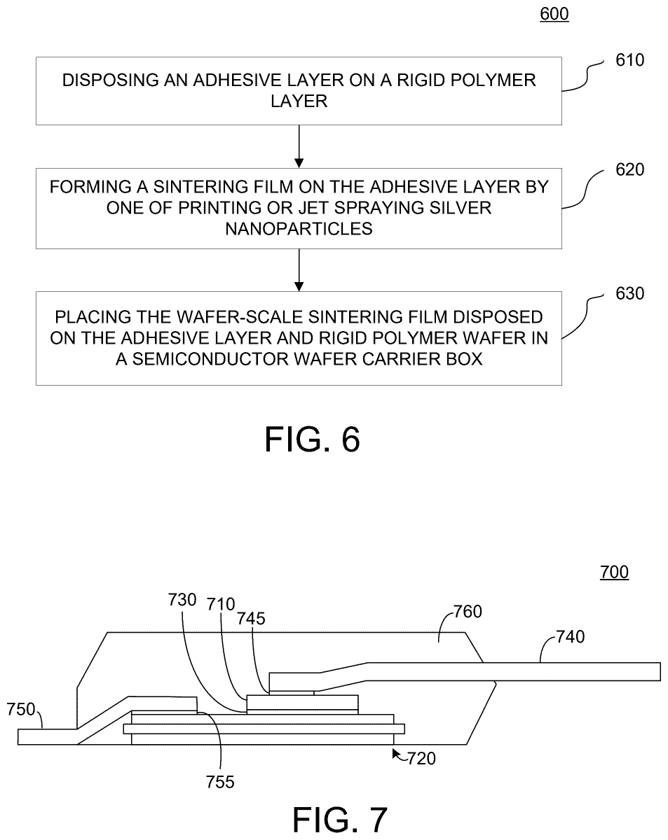

FIG. 6 is a flowchart illustrating an example method for producing a wafer-scale sintering film. In example implementations, the method 600 can be used to produce a wafer-level sintering film, such as the wafer-scale sintering film 110, the wafer-scale sintering film 210a or the wafer-scale sintering film 210b. At block 610, the method 600 includes disposing an adhesive layer (adhesive layer 120) on a rigid polymer layer (protective layer 130). At block 620, the method 600 includes forming a sintering film (wafer-scale sintering film 110, wafer-scale sintering film 210a, wafer-scale sintering film 210b) on the adhesive layer by at least one of printing or jet spraying silver nanoparticles (e.g., nano Ag-filler). In some implementations, forming the sintering film at block 620 can include cutting a sintering film, along with an adhesive layer and protective layer, to a desired size, such as a standard wafer size. At block 630, the method 600 includes placing the wafer-scale sintering film stack (sintering film stack 100) in a wafer carrier box. In some implementations, the wafer-scale sintering film stack can be mounted in a wafer support ring, and then placed in a wafer carrier box for shipping, handling and/or storage.

FIG. 7 is a diagram illustrating an example semiconductor device assembly 700 that can be produced using the approaches described herein in conjunction with other assembly processing operations. The semiconductor device assembly 700 includes semiconductor die 710 that is coupled with a substrate 720 via first sintering film portion 730. The substrate 720 can be a direct-bonded metal substrate (such a direct-bonded copper substrate). In some implementations, a die attach paddle, e.g., a copper die attach paddle, could be implemented in place of the substrate 720.

The semiconductor device assembly 700 also includes a signal lead 740 (or conductive clip) that is coupled with the semiconductor die 710 via a second sintering film portion 745. The semiconductor device assembly 700 further includes a signal lead 750 (or conductive clip) that is coupled with the substrate 720 via a third sintering film portion 755. The first sintering film portion 730, the second sintering film portion 745, and the third sintering film portion 755 can be included in (placed and attached to corresponding surfaces of) the semiconductor device assembly 700 using the approaches of, e.g., FIGS. 4A to 4F and of the method 500 of FIG. 5. As shown in FIG. 7, the semiconductor device assembly 700 also includes a molding compound 760 that encapsulates portions of the semiconductor device assembly 700.

The approaches described herein can provide a number of advantages. For instance, the disclosed approaches allow for handling sintering film wafers using existing wafer handling and die bonding equipment with minor modifications, rather than requiring purchase and/or design of additional processing equipment. The disclosed approaches improve sintering film hot tack processing (e.g., through the use of a UV curable adhesive layer), which can improve quality and reduce costs (due to lowering yield loss). The disclosed approaches can provide manufacturing throughput (UPH) improvement over prior approaches, as well as allow for use of larger sintering films due to elimination of the use of custom trays. The disclosed approaches can also reduce material loss due to handling damage due to, at least, contact with walls of tray pockets, polymer tape release, and/or peeling due to contamination.

In a general aspect, a method includes coupling a sintering film with a carrier tape and cutting the sintering film into a plurality of sintering film portions. The method further includes removing a sintering film portion of the plurality of sintering film portions from the carrier tape and disposing the sintering film portion on a surface of a semiconductor device assembly. The method also includes performing a thermal operation to couple the sintering film portion to the surface of the semiconductor device assembly.

Implementations can include one or more of the following feature or aspects, alone or in combination. For example, the sintering film can be a wafer-scale, silver-based sintering film.

The sintering film can be coupled with a polymer layer via an adhesive. Cutting the sintering film into the plurality of sintering film portions can include cutting the polymer layer into a plurality of polymer layer portions. Removing the sintering film portion from the carrier tape can include removing the sintering film portion and a respective polymer layer portion of the plurality of polymer layer portions from the carrier tape with a vacuum head.

The adhesive can be an ultraviolet light curable acrylate.

The carrier tape can be a low-tack resilient polymer tape. The polymer layer cab be a rigid polymer layer.

The method can include, prior to performing the thermal operation, curing an adhesive disposed between the respective polymer layer portion and the sintering film portion. The adhesive disposed between the respective polymer layer portion and the sintering film portion can be a portion of the adhesive coupling the polymer layer to the sintering film. The method can include, after performing the thermal operation, removing the respective polymer layer portion from the sintering film portion with the vacuum head.

Curing the adhesive can include curing the adhesive with at least one ultraviolet light included in an optical inspection station.

The sintering film portion can be a first sintering film portion. The method can include, after removing the respective polymer layer portion from the first sintering film portion: disabling a vacuum pressure applied to the vacuum head to release the respective polymer layer portion from the vacuum head and, after reapplying the vacuum pressure to the vacuum head, removing a second sintering film portion of the plurality of sintering film portions from the carrier tape. The first sintering film portion can be a first size, and the second sintering film portion can be a second size different from the first size.

The surface of the semiconductor device assembly can be a surface of a first component of the semiconductor device assembly. The method can include disposing a surface of a second component of the semiconductor device assembly on the sintering film portion on an opposite side of the sintering film portion from the surface of the first component of the semiconductor device assembly. The method can include performing a sinter operation to electrically and physically couple the first component of the semiconductor device assembly with the second component of the semiconductor device assembly.

The first component of the semiconductor device assembly can be one of a substrate or a die attach paddle. The second component of the semiconductor device assembly can be one of a semiconductor die, a signal lead, or a conductive clip.

The first component of the semiconductor device assembly can be a semiconductor die. The second component of the semiconductor device assembly can be one of a signal lead or a conductive clip.

In another general aspect, a system for placement of sintering material in a semiconductor device assembly includes a pick and place apparatus, and a device assembly apparatus. The pick and place apparatus is configured to remove a portion of a sintering film from a carrier tape, and place the portion of the sintering film on a surface of the semiconductor device assembly, where the semiconductor device assembly is disposed on the device assembly apparatus, The device assembly apparatus is configured, after placement of the portion of the sintering film, to perform a thermal operation to couple the portion of the sintering film with the surface of the semiconductor device assembly.

Implementations can include one or more of the following features or aspects, alone or in combination. For example, the sintering film can be a wafer-scale sintering film. The carrier tape can be a die-transfer film.

The pick and place apparatus can include a vacuum head configured to remove the portion of the sintering film from the carrier tape and place the portion of the sintering film on the surface of the semiconductor device assembly. The pick and place apparatus can include a pepper pot configured to support the sintering film and the carrier tape during removal of the portion of the sintering film. The pepper pot can include a rubber surface configured to contact the carrier tape on an opposite side from the sintering film.

The device assembly apparatus can include a heat source for performing the thermal operation.

The system can include an inspection apparatus configured for visual inspection of the portion of the sintering film. The inspection apparatus can include at least one ultraviolet light for curing an adhesive coupling the portion of the sintering film with a polymer layer disposed on a surface of the portion of the sintering film opposite the carrier tape.

In another general aspect, a method includes disposing an adhesive layer on a rigid polymer layer, and forming a sintering film on the adhesive layer by one of printing or jet spraying silver nanoparticles. The sintering film is a wafer-scale sintering film.

Implementations can include one or more of the following features or aspects, alone or in combination. For example, the adhesive layer can be an ultraviolet light curable acrylate.

The method can include placing the wafer-scale sintering film disposed on the adhesive layer and rigid polymer wafer in a semiconductor wafer carrier box.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A method comprising:
coupling a sintering film with a carrier tape;
cutting the sintering film into a plurality of sintering film portions;
removing a sintering film portion of the plurality of sintering film portions from the carrier tape;
disposing the sintering film portion on a surface of a semiconductor device assembly; and
performing a thermal operation to couple the sintering film portion to the surface of the semiconductor device assembly.

2. The method of claim 1, wherein the sintering film is a wafer-scale, silver-based sintering film.

3. The method of claim 1, wherein:
the sintering film is coupled with a polymer layer via an adhesive;
cutting the sintering film into the plurality of sintering film portions includes cutting the polymer layer into a plurality of polymer layer portions; and
removing the sintering film portion from the carrier tape includes removing the sintering film portion and a respective polymer layer portion of the plurality of polymer layer portions from the carrier tape with a vacuum head.

4. The method of claim 3, wherein the adhesive is an ultraviolet light curable acrylate.

5. The method of claim 3, wherein:
the carrier tape is a low-tack resilient polymer tape; and
the polymer layer is a rigid polymer layer.

6. The method of claim 3, further comprising:
prior to performing the thermal operation, curing an adhesive disposed between the respective polymer layer portion and the sintering film portion, the adhesive disposed between the respective polymer layer portion and the sintering film portion being a portion of the adhesive coupling the polymer layer to the sintering film; and
after performing the thermal operation, removing the respective polymer layer portion from the sintering film portion with the vacuum head.

7. The method of claim 6, wherein curing the adhesive includes curing the adhesive with at least one ultraviolet light included in an optical inspection station.

8. The method of claim 6, wherein the sintering film portion is a first sintering film portion, the method further comprising, after removing the respective polymer layer portion from the first sintering film portion:
disabling a vacuum pressure applied to the vacuum head to release the respective polymer layer portion from the vacuum head; and
after reapplying the vacuum pressure to the vacuum head, removing a second sintering film portion of the plurality of sintering film portions from the carrier tape.

9. The method of claim 8, wherein:
the first sintering film portion is a first size; and
the second sintering film portion is a second size different from the first size.

10. The method of claim 1, wherein the surface of the semiconductor device assembly is a surface of a first component of the semiconductor device assembly, the method further comprising:
disposing a surface of a second component of the semiconductor device assembly on the sintering film portion on an opposite side of the sintering film portion from the surface of the first component of the semiconductor device assembly; and
performing a sinter operation to electrically and physically couple the first component of the semiconductor device assembly with the second component of the semiconductor device assembly.

11. The method of claim 10, wherein:
the first component of the semiconductor device assembly is one of a substrate or a die attach paddle; and
the second component of the semiconductor device assembly is one of a semiconductor die, a signal lead, or a conductive clip.

12. The method of claim 10, wherein:
the first component of the semiconductor device assembly is a semiconductor die; and
the second component of the semiconductor device assembly is one of a signal lead or a conductive clip.

13. A system for placement of sintering material in a semiconductor device assembly, the system comprising:
a pick and place apparatus; and
a device assembly apparatus,
the pick and place apparatus being configured to:
remove a portion of a sintering film from a carrier tape; and
place the portion of the sintering film on a surface of the semiconductor device assembly, the semiconductor device assembly being disposed on the device assembly apparatus, and
the device assembly apparatus being configured, after placement of the portion of the sintering film, to perform a thermal operation to couple the portion of the sintering film with the surface of the semiconductor device assembly.

14. The system of claim 13, wherein:
the sintering film is a wafer-scale sintering film; and
the carrier tape is a die-transfer film.

15. The system of claim 13, wherein the pick and place apparatus includes:
a vacuum head configured to remove the portion of the sintering film from the carrier tape and place the portion of the sintering film on the surface of the semiconductor device assembly; and
a pepper pot configured to support the sintering film and the carrier tape during removal of the portion of the sintering film, the pepper pot including a rubber surface configured to contact the carrier tape on an opposite side from the sintering film.

16. The system of claim 13, wherein the device assembly apparatus includes a heat source for performing the thermal operation.

17. The system of claim 15, further comprising an inspection apparatus configured for visual inspection of the portion of the sintering film, the inspection apparatus includes at least one ultraviolet light for curing an adhesive coupling the portion of the sintering film with a polymer layer disposed on a surface of the portion of the sintering film opposite the carrier tape.

18. A method comprising:
disposing an adhesive layer on a rigid polymer layer; and
forming a sintering film on the adhesive layer by one of printing or jet spraying silver nanoparticles, the sintering film being a wafer-scale sintering film.

19. The method of claim 18, wherein the adhesive layer is an ultraviolet light curable acrylate.

20. The method of claim 18, further comprising:
placing the wafer-scale sintering film disposed on the adhesive layer and rigid polymer wafer in a semiconductor wafer carrier box.
